(19) United States
(12) Patent Application Publication
(10) Pub. No.: US 2020/0044152 A1
(43) Pub. Date: Feb. 6, 2020

(54) PHYSICAL VAPOR DEPOSITION OF DOPED TRANSITION METAL OXIDE AND POST-DEPOSITION TREATMENT THEREOF FOR NON-VOLATILE MEMORY APPLICATIONS

(71) Applicant: APPLIED MATERIALS, INC., Santa Clara, CA (US)

(72) Inventors: MINRUI YU, SAN JOSE, CA (US); ANINDITA SEN, SAN JOSE, CA (US); VIBHU JINDAL, SAN JOSE, CA (US); MICHEL FREI, Palo Alto, CA (US); MAHENDRA PAKALA, Fremont, CA (US); MEHUL NAIK, SAN JOSE, CA (US); NICOLAS BREIL, SAN JOSE, CA (US); MICHAEL CHUDZIK, MOUNTAIN VIEW, CA (US)

(21) Appl. No.: 16/525,051

(22) Filed: Jul. 29, 2019

Related U.S. Application Data
(60) Provisional application No. 62/712,739, filed on Jul. 31, 2018.

(51) Int. Cl. H01L 45/00; C23C 14/34; C23C 14/14; C23C 14/08

(52) U.S. Cl. CPC H01L 45/1625; H01L 45/1253; H01L 45/146; C23C 14/08; C23C 14/3464; C23C 14/14; H01L 45/1233

(57) ABSTRACT

Embodiments of methods for depositing doped transition metal oxides are provided herein. In some embodiments, a method of depositing a doped transition metal oxide layer includes: sputtering a first target comprising a transition metal while providing a source of oxygen atoms; sputtering a second target comprising a dopant element; and forming a doped transition metal oxide layer on a substrate from the sputtered transition metal, oxygen atoms, and dopant element. The first target can be formed from a transition metal or a transition metal oxide.

### CROSS-REFERENCE TO RELATED APPLICATIONS

This application claims benefit of U.S. provisional patent application Ser. No. 62/712,739, filed Jul. 31, 2018, which is herein incorporated by reference.

### FIELD

Embodiments of the present disclosure generally relate to semiconductor processing techniques, and more particularly, to techniques for physical vapor deposition of materials on a substrate.

### BACKGROUND

Non-volatile memory (NVM) is useful for low-power electronics as NVM can retain information even after power is turned off. The inventors have observed a recent development in the NVM family that relies on doped transition metal oxides (TMO) that undergo Mott Transition, where a TMO changes from being a good electrical insulator to a good electrical conductor, and vice versa. The inventors have observed problems with doped TMO films deposited via chemical vapor deposition (CVD) or atomic layer deposition (ALD), which are the conventional techniques for depositing such films. Specifically, the inventors have observed problems such as outgassing, low adhesion, and contamination due to the chemical precursors used to deposit the films.

Therefore, the inventors have provided improved techniques for depositing doped transition metal oxides.

### SUMMARY

Embodiments of methods for depositing doped transition metal oxides are provided herein. In some embodiments, a method of depositing a doped transition metal oxide layer includes: sputtering a first target comprising a transition metal while providing a source of oxygen atoms; sputtering a second target comprising a dopant element; and forming a doped transition metal oxide layer on a substrate from the sputtered transition metal, oxygen atoms, and dopant element. The first target can be formed from a transition metal or a transition metal oxide.

In some embodiments, a method of depositing a doped transition metal oxide layer includes: depositing a first doped transition metal oxide layer atop a first metal layer on a substrate by sputtering a first target comprising a transition metal while providing a source of oxygen atoms and sputtering a second target comprising a dopant element; and depositing a second doped transition metal oxide layer atop the first doped transition metal oxide by sputtering the first target while providing a source of oxygen atoms and sputtering the second target, wherein the stoichiometry of the first doped transition metal oxide is different than the stoichiometry of the second doped transition metal oxide. The first target can be formed from a transition metal or a transition metal oxide.

In some embodiments, a method of depositing a doped transition metal oxide layer includes: depositing a first doped transition metal oxide layer atop a first metal layer on a substrate by sputtering a first target comprising a transition metal while providing a source of oxygen atoms and sputtering a second target comprising a dopant element; depositing a second doped transition metal oxide layer atop the first doped transition metal oxide by sputtering the first target while providing a source of oxygen atoms and sputtering the second target, wherein the stoichiometry of the first doped transition metal oxide is different than the stoichiometry of the second doped transition metal oxide; and depositing a second metal layer atop the second doped transition metal oxide layer, wherein the first metal layer comprises a first electrode of a non-volatile memory structure, the first doped transition metal oxide layer comprises a buffer layer of the non-volatile memory structure, the second doped transition metal oxide layer comprises a switching layer of the non-volatile memory structure, and the second metal layer comprises a second electrode of the non-volatile memory structure. The first target can be formed from a transition metal or a transition metal oxide.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flow chart of a method of depositing a doped transition metal oxide layer in accordance with at least some embodiments of the present disclosure.

FIG. 2 is a flow chart of a method of depositing a doped transition metal oxide layer in accordance with at least some embodiments of the present disclosure.

FIG. 3 is a schematic side view of a partially formed microelectronic device structure having a doped transition metal oxide layer in accordance with at least some embodiments of the present disclosure.

FIG. 4 is a schematic side view of a partially formed microelectronic device structure having a doped transition metal oxide layer in accordance with at least some embodiments of the present disclosure.

FIG. 5 depicts a schematic view of a multi-cathode physical vapor deposition (PVD) chamber suitable for performing at least portions of the methods described herein in accordance with some embodiments of the present disclosure.

FIG. 6 depicts a bottom view of a shield disposed in the multi-cathode PVD chamber of FIG. 5 in accordance with some embodiments of the present disclosure.

FIG. 7 depicts a partial schematic view of an upper portion of a multi-cathode PVD chamber suitable for performing at least portions of the methods described herein in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods for depositing doped transition metal oxides are provided herein. Embodiments of the present disclosure use PVD (physical vapor deposition) co-sputtering to deposit a doped TMO, such as for example, carbon-doped nickel oxide. In particular, the PVD chamber has more than one cathode. Each cathode has a corresponding target, with at least one target dedicated to the TMO (e.g., Ni or NiO) and at least one other target dedicated to the dopant (e.g., C). Each cathode also has a corresponding power supply, which can provide either DC, or pulsed DC, or RF power to strike plasma for the target. Individual power supplies advantageously allows individual tuning of the amount of materials deposited, and hence the composition of the final compound. In addition, the plasma of all targets during co-sputtering is shared, which can enhance each other and change individual characteristics as compared to running each individually. The PVD chamber can hold up to five different cathodes/targets. A rotating shield with opening holes regulates which target (or targets) gets deposited, such that only when a target is aligned with the opening hole, will material from that target be deposited on to the wafer. A high-temperature electrostatic chuck (HT-ESC) can also be used to heat up the wafer, for example, to promote crystallinity of the film.

In some exemplary configurations, Ni and C targets are co-sputtered with Ar and O₂ flow. Alternatively, a NiO target can be co-sputtered with a C target in Ar, with or without O₂. Other combinations of other transition metals or transition metal oxides and other dopants can also be used, as discussed in more detail below. The inventors have discovered that using multiple targets in a co-sputtering process advantageously provides greater flexibility in terms of control of the film composition or stoichiometry. For example, selecting a main target material such as nickel (Ni), nickel oxide (NiO), nickel carbide (Ni₃C), or nickel carbonate (NiCO₃), advantageously provides different bonding options to start with.

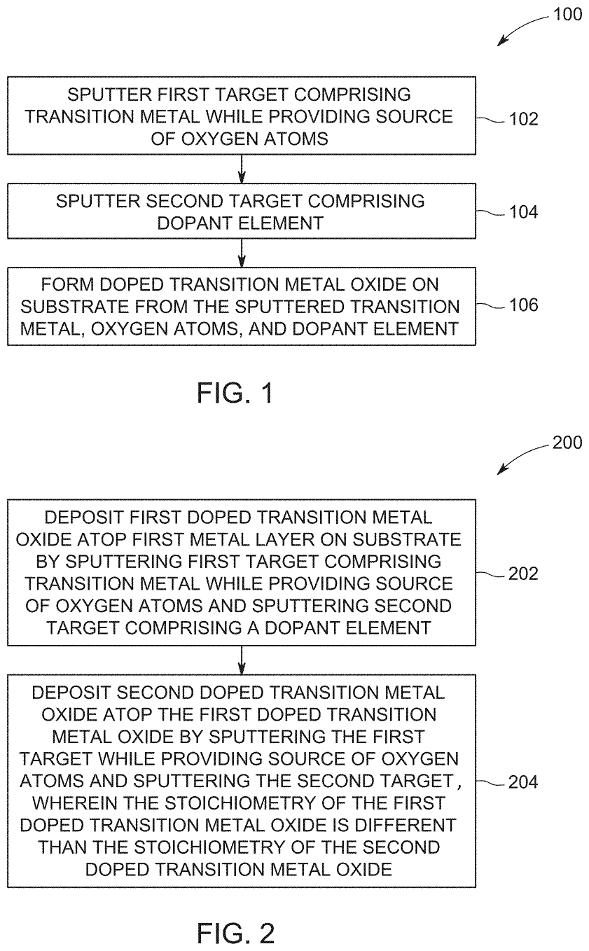

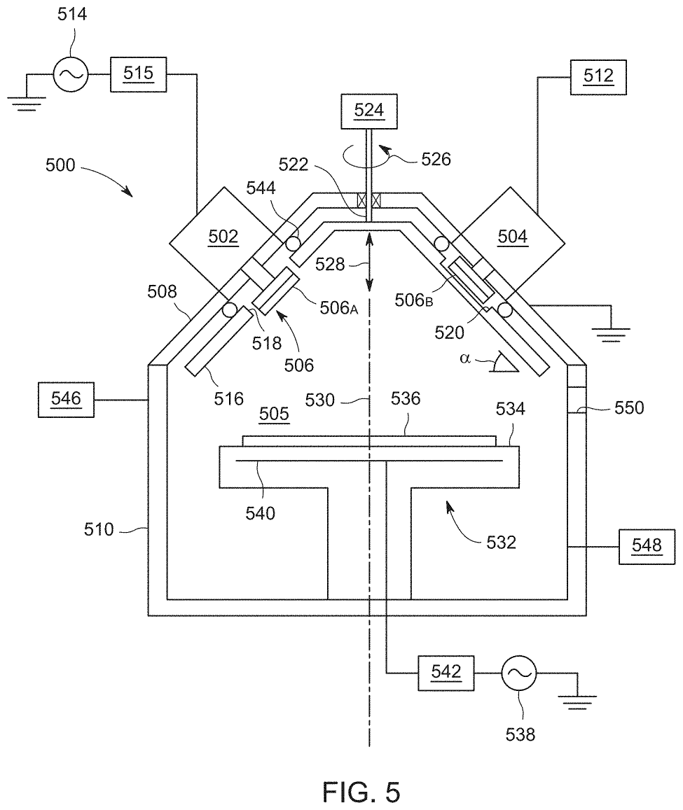

For example, FIG. 1 is a flow chart of a method 100 of depositing a doped transition metal oxide layer in accordance with at least some embodiments of the present disclosure. The method 100 can be performed in a multi-cathode physical vapor deposition (PVD) chamber, such as described below with respect to FIGS. 5-7.

As depicted in FIG. 1, a method 100 of depositing a doped transition metal oxide layer generally begins at 102 where a first target comprising a transition metal is sputtered while providing a source of oxygen atoms. The source of oxygen atoms can be the target itself (e.g., where the target comprises a transition metal oxide), oxygen gas (O₂) provided to the PVD chamber, or both. For example, in some embodiments, the first target is substantially free of oxygen and the oxygen source is oxygen gas (O₂) provided to the PVD chamber. In some embodiments, the first target includes oxygen (e.g., the target is a transition metal oxide) and substantially no oxygen gas (O₂) is provided to the PVD chamber. In some embodiments, the first target includes oxygen (e.g., the target is a transition metal oxide) and oxygen gas (O₂) is provided to the PVD chamber.

The first target comprised a transition metal or a transition metal oxide. For example, in some embodiments, the first target can be formed of a transition metal such as nickel, tantalum, vanadium, or zirconium. In some embodiments, the first target is nickel (Ni), vanadium (V), or zirconium (Zr). In some embodiments, the first target is nickel oxide (NiO), vanadium oxide (V₂O₃), or zirconium oxide (ZrO). In some embodiments, the first target is nickel (Ni) or nickel oxide (NiO).

As shown at 104, a second target comprising a dopant element is sputtered to provide a dopant element. For example, in some embodiments, the second target can be formed of a dopant material such as carbon, tungsten, or titanium. The first target and the second target are sputtered at the same time in order to provide the transition metal, oxygen, and dopant atoms to form the doped transition metal oxide layer. Thus, as depicted at 106 a doped transition metal oxide layer is formed on the substrate from the sputtered transition metal, oxygen atoms, and dopant element. In some embodiments, the doped transition metal oxide comprises NiO/C, NiO/CW, V₂O₃/C, V₂O₃/Ti, V₂O₃/CTi, or ZrO/C. In some embodiments, the doped transition metal oxide comprises NiO/C.

The sputter deposition process can be performed under suitable conditions to control the characteristics of the deposited doped transition metal oxide layer. For example, the inventors have discovered that the composition, stoichiometry, adhesion to underlying layers, and the like, can be advantageously controlled using the techniques described herein.

For example, the stoichiometry of the transition metal oxide can advantageously be controlled by control of the deposition power of the transition metal or transition metal oxide target and the flow of oxygen gas (O₂) during sputtering. The inventors have observed that such control can affect final doped transition metal oxide resistivity and, for example in memory or transistor applications, can result in films that are initially “on”, or affect the doped transition metal oxide band gap. For example, the bandgap can be controlled by increasing the bandgap with increased oxygen content and decreased bandgap with lower oxygen content.

Alternatively, or in combination, the respective transition metal or transition metal oxide and dopant material deposition powers can be controlled to control the dopant concentration in the doped transition metal oxide layer, which will advantageously control the band structure and σ*-bond to π*-bond ratio.

Alternatively, or in combination, the deposition temperature can be controlled to tune the amount of electrons in the transition metal at particular spin-orbital states and/or to control the grain size of the doped transition metal oxide film.

Alternatively, or in combination, substrate bias application and/or low process pressure can be used to promote more energetic ions during deposition, thus controlling the bonding characteristics of the deposited film.

In addition, for certain applications, the inventors have discovered than the crystalline orientation of the doped transition metal oxide films can be controlled to promote Mott Transition. The inventors have observed that (111) and (200) crystal orientations are beneficial for Mott Transition. The inventors have discovered that doped transition metal oxides formed by PVD co-sputtering techniques as disclosed herein can be deposited with predominant (111) and (200) crystal orientations. In addition, the inventors have discovered that the crystal orientation of doped transition metal oxide films can be controlled by control of the underlying substrate materials, depositing a seed layer, or control of the oxygen flow during deposition.

For example, in some embodiments, a seed layer can be deposited atop the substrate prior to depositing the first doped transition metal oxide layer. In some embodiments, the seed layer can be annealed prior to depositing the first doped transition metal oxide layer atop the seed layer. The seed layer can be annealed in-situ, using for example, heaters disposed in the substrate support to heat the substrate to the anneal temperature. Alternatively, or in combination, the underlying substrate material, such as an underlying metal layer, can be annealed prior to deposition of the doped transition metal oxide layer to promote growth in a particular crystal orientation.

The flexibility in PVD co-sputtering allows fabrication of stacked structures. For example, a transition metal oxide (TMO) active layer can be deposited atop a buffer layer. The buffer layer can be sub-stoichiometric TMO or heavily doped TMO. The bottom buffer layer, which is more conductive or with more doping, can increase the supply of holes available for injection into the switching TMO region. In some embodiments, to make the transition smoother, the stoichiometry level or doping concentration in the buffer layer can have a gradient, or be gradually changed to match, or be closer to, that of the active layer. Alternatively, or in combination, the active TMO layer can be sandwiched between two buffer layers. The buffer layers can have different levels of stoichiometry or doping concentration, and can have a fixed or gradient stoichiometry or doping concentration. The sandwich structure has the benefit of separating the active TMO layer from any defects in adjacent contact metal layers.

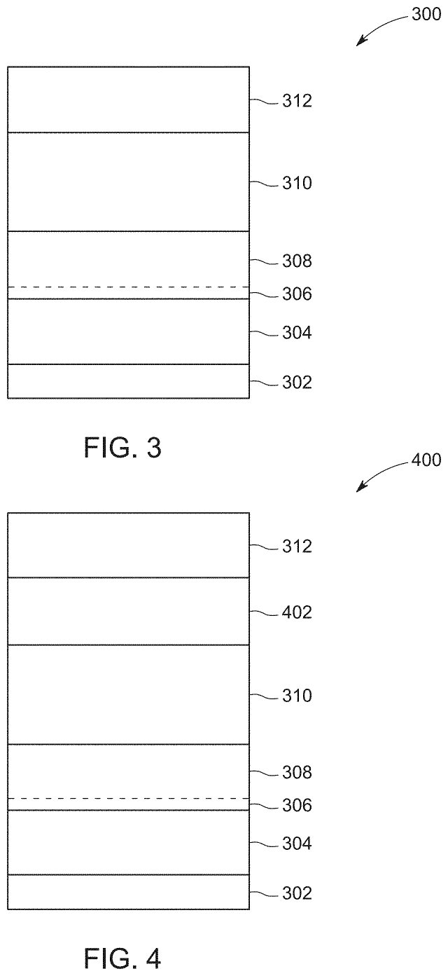

For example, FIG. 2 is a flow chart of a method 200 of depositing a doped transition metal oxide layer in accordance with at least some embodiments of the present disclosure. FIGS. 3 and 4 are schematic side views of a partially formed microelectronic device structure having a doped transition metal oxide layer in accordance with at least some embodiments of the present disclosure. The method 200 generally begins at 202 where a first doped transition metal oxide layer 308 is deposited atop a first metal layer 304 on a substrate 302 by sputtering a first target comprising a transition metal while providing a source of oxygen atoms and sputtering a second target comprising a dopant element.

Next, as shown at 204, a second doped transition metal oxide layer 310 is deposited atop the first doped transition metal oxide 308 by sputtering the first target while providing a source of oxygen atoms and sputtering the second target, wherein the stoichiometry of the first doped transition metal oxide is different than the stoichiometry of the second doped transition metal oxide.

The inventors have discovered that the herein disclosed deposition techniques are advantageous in certain applications, such as non-volatile memory applications. Therefore, in some embodiments, the substrate 302 can be an interconnect or a source/drain region of a transistor. A second metal layer 312 can deposited atop the second doped transition metal oxide layer 310, wherein the first metal layer 304 comprises a first electrode of a non-volatile memory structure 300, 400, the first doped transition metal oxide layer 308 comprises a buffer layer of the non-volatile memory structure, the second doped transition metal oxide layer 310 comprises a switching layer of the non-volatile memory structure, and the second metal layer 312 comprises a second electrode of the non-volatile memory structure.

In the above example, the second metal layer 312 can advantageously be deposited in the same chamber as the first and second doped transition metal oxide layers 308, 310, thus avoiding exposure to atmosphere which can lead to oxidation, contamination, outgassing, or other issues. In some embodiments, the first and second metal layers 304, 312 comprise a conductive material such as W, TaN, Ir, or Pt.

In some embodiments, the first metal layer, first doped transition metal oxide layer, second doped transition metal oxide layer, and the second metal layer can be annealed. In some embodiments, the substrate including the first metal layer, first doped transition metal oxide layer, second doped transition metal oxide layer, and the second metal layer can be annealed in a process such as a laser anneal process, a rapid thermal processing (RTP) anneal process, or the like.

As discussed above with respect to FIG. 1, a seed layer 306 can optionally be deposited atop the first metal layer prior to depositing the first doped transition metal oxide layer. In addition, the seed layer 306 can be annealed prior to depositing the first doped transition metal oxide layer. The seed layer 306 can be annealed in-situ, using for example, heaters disposed in the substrate support to heat the substrate to the anneal temperature.

In some embodiments and as illustrated in FIG. 4, a third doped transition metal oxide layer 402 can be deposited atop the second doped transition metal oxide layer 310 prior to depositing the second metal layer 312, wherein the stoichiometry of the third doped transition metal oxide is different than the stoichiometry of the second doped transition metal oxide.

In some embodiments, the stoichiometry of the first doped transition metal oxide can be varied during deposition of the first doped transition metal oxide layer to gradually match, or be closer to, the stoichiometry of the second doped transition metal oxide. In some embodiments, the stoichiometry of the third doped transition metal oxide can be varied during deposition of the third doped transition metal oxide layer from an initial stoichiometry that matches or is closer to the stoichiometry of the second doped transition metal oxide then moves further away from the stoichiometry of the second doped transition metal oxide as the thickness of the third doped transition metal oxide layer increases. For example, in some embodiments, the dopant concentration can be lower in the first and third doped transition metal oxide layers as compared to the second doped transition metal oxide layer.

The methods disclosed above can be performed in a suitably configured multi-cathode physical vapor deposition (PVD) chamber. For example, FIGS. 5-7 respectively depict schematic views of a multi-cathode PVD chamber, or portions thereof, suitable for performing at least portions of the methods described herein in accordance with some embodiments of the present disclosure. In some embodiments, a multi-cathode PVD chamber (e.g., process chamber 500) includes a plurality of cathodes 502, 504 having a corresponding plurality of targets 506 (at least one transition metal target 506_{A} and at least one dopant target 506_{B}), (for example, 5 cathodes) attached to the chamber body (for example, via a chamber body adapter 508). The transition metal target(s) may be formed of a transition metal or a transition metal oxide as disclosed above. The dopant target(s) may be formed of a dopant material as disclosed above. In the embodiment shown in FIG. 5, each target is disposed at a predetermined angle α with respect to the support surface 534. In some embodiments, the angle α may be between about 10° to about 50°.

The processing chamber includes a substrate support 532 having a support surface 534 to support a substrate 536. The substrate support 532 can be, for example, an electrostatic chuck. In some embodiments, the substrate support 532 can be heated, for example using resistive heaters or the like, to facilitate in-situ heating, annealing, or the like, of the substrate 536 as discussed above. The process chamber 500 includes an opening 550 (e.g., a slit valve) through which an end effector may extend to place or remove the substrate 536 onto or off of the support surface 534. The substrate support includes an RF bias power source 538 coupled to a bias electrode 540 disposed in the substrate support 532 via a matching network 542. The chamber body adapter 508 is coupled to an upper portion of a chamber body 510 of the process chamber 500 and is grounded. Each cathode can have a DC power source 512 or an RF power source 514 and an associated magnetron. In the case of the RF power source 514, the RF power source 514 is coupled to the cathode via an RF matching network 515. The RF energy supplied by the RF power source 514 may range in frequency from about 13.56 MHz and to about 162 MHz or above. For example, non-limiting frequencies such as 13.56 MHz, 27.12 MHz, 60 MHz, or 162 MHz can be used.

The RF bias power source 538 may be coupled to the substrate support 532 in order to induce a negative DC bias on the substrate 536. In addition, in some embodiments, a negative DC self-bias may form on the substrate 536 during processing. For example, RF energy supplied by the RF bias power source 538 may range in frequency from about 2 MHz to about 60 MHz, for example, non-limiting frequencies such as 2 MHz, 13.56 MHz, or 60 MHz can be used. In other applications, the substrate support 532 may be grounded or left electrically floating.

A shield 516 is rotatably coupled to the chamber body adapter 508 and is shared by all the cathodes. Depending on the number of targets that need to be sputtered at the same time, the rotating shield 516 can have one or more holes to expose a corresponding one or more targets. The shield 516 advantageously limits or eliminates cross-contamination between the plurality of targets 506. For example, in some embodiments where five cathodes are provided, the shield 516 may include at least one hole 518 to expose a target to be sputtered and at least one pocket 520 to house a target that is not being sputtered. The shield 516 is rotationally coupled to the chamber body adapter 508 via a shaft 522. In some embodiments, the shield 516 has one or more sidewalls configured to surround a processing volume within the inner or interior volume 505.

An actuator 524 is coupled to the shaft 522 opposite the shield 516. The actuator 524 is configured to rotate the shield 516, as indicated by arrow 526, and move the shield 516 up and down along a central axis 530 of the process chamber 500, as indicated by arrow 528. When the shield 516 is moved up into a retracted position so that a face of the shield surrounding the hole 518 is behind a face of the target (e.g., transition metal target 506_{A}) facing the substrate 536, materials sputtered in a dark space surrounding the target (e.g., on a sidewall of the hole 518) are advantageously minimized. As a result, materials sputtered from one target (e.g. transition metal target 506_{A}) do not contaminate another target (e.g., dopant target 506_{B}) due to sputtering of material that has accumulated in the dark space.

In some embodiments, the shield 516 may be provided with a pocket 520 to house a target not being sputtered. The pocket advantageously prevents scattering of the sputtered target from being deposited on the target not being sputtered. Although such scattering is inevitable, the pocket 520 ensures that the scattering does not contaminate the sputtered surface of the non-sputtered target. As a result, contamination of the target not being sputtered is further reduced.

In some embodiments, the process chamber 500 includes a plurality of RF grounding rings 544 to provide improved grounding of the shield 516 to the grounded chamber body adapter 508 when the shield is in the retracted position. The RF grounding rings 544 advantageously prevent the shield 516 from getting negatively charged by minimizing the energy between the plasma and the shield.

The process chamber 500 further includes a process gas supply 546 to supply a predetermined process gas to an interior volume 505 of the process chamber 500. For example, the process gas supply 546 may supply oxygen to the interior volume 505. The process chamber 500 also includes an exhaust pump 548 fluidly coupled to the interior volume 505 to exhaust the process gas and to facilitate in maintaining a desired pressure inside the process chamber 500.

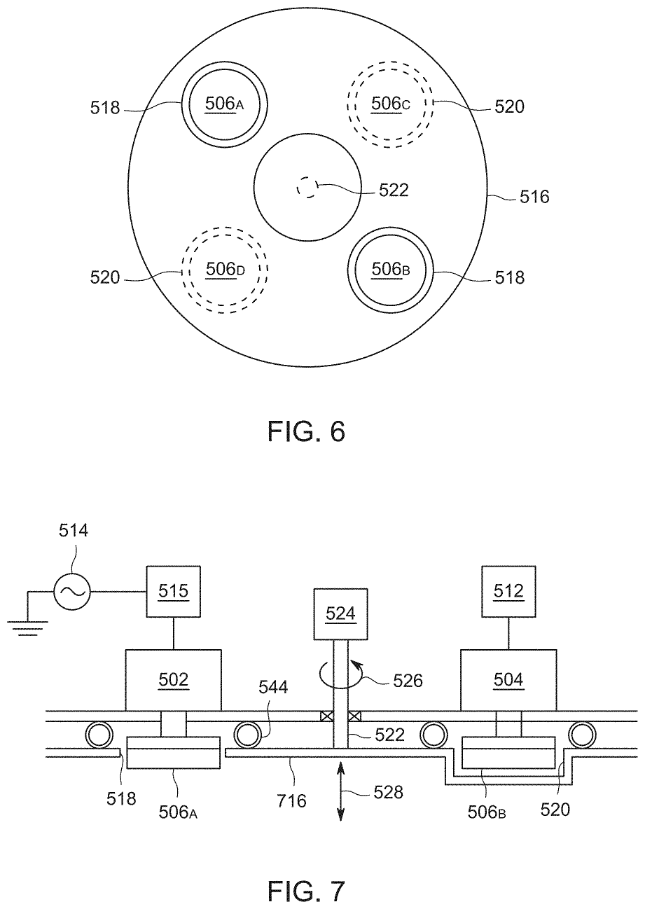

FIG. 6 depicts a bottom view of the shield 516 of FIG. 5 in accordance with some embodiments of the present disclosure. In FIG. 6, the plurality targets 506 are illustrated as four targets (e.g., 506_{A}-506_{D}). In some embodiments, the shield 516 may include two holes 518 and two pockets 520. For example, the two holes may be aligned with a first target 506_{A} (corresponding to a transition metal or transition metal oxide material to be sputtered), and a second target 506_{D} (corresponding to a dopant material to be co-sputtered, or simultaneously sputtered, with the first target). In some embodiments, the at least one of the remaining targets covered by the shield (e.g., 506_{c}-506_{D}) is a third target corresponding to a metal material to be deposited, for example, to form an electrode layer of a non-volatile memory structure in accordance with the teachings herein.

Although in FIG. 6, the plurality targets 506 are illustrated as four targets (e.g., 506_{A}-506_{D}), greater or fewer targets may be utilized. In addition, although FIG. 6 depicts two holes 518 and two pockets 520, the shield 516 may alternatively include different numbers of holes 518 and pockets 520 to expose less or more than two targets to be simultaneously sputtered.

FIG. 7 depicts a close-up of an upper portion of a multi-cathode PVD chamber in accordance with some embodiments of the present disclosure. As shown in FIG. 7, a shield 716 having a flat orientation may be used instead of the angled shield 516 in the process chamber 500 shown in FIG. 5. In the embodiment shown in FIG. 7, the targets 506_{A}, 506_{B} are parallel to the support surface 534, rather than at an angle. The shield 716 includes one or more holes 518 to expose one or more targets 506 to be sputtered. The shield 716 also includes one or more pockets 520 to house one or more targets 506 that are not being sputtered.

Compared to ALD or CVD approaches, the PVD multi-cathode co-sputtering process of the present disclosure has one or more of following advantages: no risk of outgassing and better adhesion (PVD film is not as prone to outgassing and hence less likelihood of losing film species, such as carbon, during subsequent elevated temperature processes, e.g., anneal, and less risk of delamination); good uniformity in terms of composition and thickness (the inventors have tested and observed that multi-cathode PVD co-sputtering can provide a NU of <2%); good roughness (PVD TMO film roughness can be <7 Å for a 300 Å film); improved control of the TMO stoichiometry (for example, various degrees of sub-stoichiometric TMO can be achieved by adjusting oxygen and deposition power so that oxygen and metal atomic ratio can be changed in the TMO compound); flexible in the carbon doping concentration as well as profile, including a concentration gradient if desired (dopant concentration can be easily adjusted by deposition power, which can even be changed continuously); flexible in doping species, instead of or in addition to carbon (e.g., co-sputtering allows simultaneous deposition of 2 or more elements, such as non-limiting examples of NiO and C, or NiO and C and W, V₂O₃ and C and/or Ti, or ZrO and C); or in-situ deposition of metal layers with TMO layers (e.g., the multi-cathode chamber allows installation of metal target for a metal layer, such as an electrode, in the same chamber with the TMO targets, thus avoiding air break that could adversely impact film properties).

While the foregoing is directed to embodiments of the present disclosure, other and further embodiments of the disclosure may be devised without departing from the basic scope thereof.

1. A method of depositing a doped transition metal oxide layer, comprising:
sputtering a first target comprising a transition metal while providing a source of oxygen atoms;
sputtering a second target comprising a dopant element; and
forming a doped transition metal oxide layer on a substrate from the sputtered transition metal, oxygen atoms, and dopant element.

2. The method of claim 1, wherein the first target comprises nickel, tantalum, vanadium, zirconium, or a corresponding metal oxide thereof.

3. The method of claim 1, wherein the dopant element comprises carbon, tungsten, or titanium.

4. The method of claim 1, wherein the doped transition metal oxide comprises NiO/C, NiO/CW, V₂O₃/C, V₂O₃/Ti, V₂O₃/CTi, or ZrO/C.

5. The method of claim 1, where the source of oxygen atoms is oxygen gas.

6. The method of claim 1, wherein the first target further comprises oxygen, and wherein the source of oxygen atoms is the first target.

7. The method of claim 1, wherein the first target and the second target are sputtered at the same time.

8. The method of claim 1, wherein the doped transition metal oxide comprises NiO/C, and wherein the first target and the second target are sputtered at the same time.

9. A method of depositing a doped transition metal oxide layer, comprising:
depositing a first doped transition metal oxide layer atop a first metal layer on a substrate by sputtering a first target comprising a transition metal while providing a source of oxygen atoms and sputtering a second target comprising a dopant element; and
depositing a second doped transition metal oxide layer atop the first doped transition metal oxide by sputtering the first target while providing a source of oxygen atoms and sputtering the second target, wherein the stoichiometry of the first doped transition metal oxide is different than the stoichiometry of the second doped transition metal oxide.

10. The method of claim 9, wherein the first metal layer comprises a first electrode of a non-volatile memory structure, and further comprising:
depositing a second metal layer atop the second doped transition metal oxide layer, wherein the second metal layer comprises a second electrode of the non-volatile memory structure.

11. The method of claim 10, wherein the second metal layer is deposited in the same chamber as the first and second doped transition metal oxide layers.

12. The method of claim 10, further comprising:
annealing the first metal layer, first doped transition metal oxide layer, second doped transition metal oxide layer, and the second metal layer.

13. The method of claim 10, wherein the first and second metal layers comprise W, TaN, Ir, or Pt.

14. The method of claim 9, further comprising:
depositing a seed layer atop the first metal layer, prior to depositing the first doped transition metal oxide layer.

15. The method of claim 14, further comprising:
annealing the seed layer prior to depositing the first doped transition metal oxide layer.

16. The method of claim 9, further comprising:
depositing a third doped transition metal oxide layer atop the second doped transition metal oxide layer, wherein the stoichiometry of the third doped transition metal oxide is different than the stoichiometry of the second doped transition metal oxide.

17. The method of claim 9, further comprising:
varying the stoichiometry of the first doped transition metal oxide during deposition of the first doped transition metal oxide layer to gradually match the stoichiometry of the second doped transition metal oxide.

18. A method of depositing a doped transition metal oxide layer, comprising:
depositing a first doped transition metal oxide layer atop a first metal layer on a substrate by sputtering a first target comprising a transition metal while providing a source of oxygen atoms and sputtering a second target comprising a dopant element;
depositing a second doped transition metal oxide layer atop the first doped transition metal oxide by sputtering the first target while providing a source of oxygen atoms and sputtering the second target, wherein the stoichiometry of the first doped transition metal oxide is different than the stoichiometry of the second doped transition metal oxide; and
depositing a second metal layer atop the second doped transition metal oxide layer, wherein the first metal layer comprises a first electrode of a non-volatile memory structure, the first doped transition metal oxide layer comprises a buffer layer of the non-volatile memory structure, the second doped transition metal oxide layer comprises a switching layer of the non-volatile memory structure, and the second metal layer comprises a second electrode of the non-volatile memory structure.

19. The method of claim 18, further comprising:
depositing a third doped transition metal oxide layer atop the second doped transition metal oxide layer, wherein the stoichiometry of the third doped transition metal oxide is different than the stoichiometry of the second doped transition metal oxide, and wherein the third doped transition metal oxide layer comprises a second buffer layer of the non-volatile memory structure.

20. The method of claim 18, wherein the doped transition metal oxide comprises NiO/C, NiO/CW, V₂O₃/C, V₂O₃/Ti, V₂O₃/CTi, or ZrO/C.
